(19) United States
(12) Patent Application Publication
(10) Pub. No.: US 2012/0003793 A1
(43) Pub. Date: Jan. 5, 2012

(54) METHOD FOR MANUFACTURING EMBEDDED SUBSTRATE

(75) Inventors: Sun-Uk HWANG, Seoul (KR); Young-Woong Cho, Daejeon (KR); Kyoung-Ro Yoon, Daejeon (KR)

(73) Assignee: SAMSUNG ELECTRO-MECHANICS CO., LTD.

(21) Appl. No.: 12/963,346

(22) Filed: Dec. 8, 2010

(30) Foreign Application Priority Data
Jul. 1, 2010 (KR) 10-2010-0063595

(51) Int. Cl. H01L 21/56

(52) U.S. Cl. 438/118; 257/E21.502

(57) ABSTRACT

A method for manufacturing an embedded substrate is disclosed. The method for manufacturing an embedded substrate, which includes a core substrate formed with a pattern on both surfaces thereof and formed with a cavity penetrating from an upper part thereof to a lower part thereof, a chip embedded in the cavity, and a first insulator and a second insulator provided respectively on either surface of the core substrate so as to protect the pattern, includes: preparing the core substrate; laminating the first insulator on a lower surface of the core substrate so as to cover a lower side of the cavity; forming an adhesive layer on the first insulator that is exposed through the cavity; embedding the chip in the cavity by attaching the chip on the adhesive layer; and laminating the second insulator on an upper surface of the core substrate.

### TECHNICAL FIELD

The present invention is related to a method for manufacturing an embedded substrate.

### BACKGROUND ART

As packages such as an embedded substrate become increasingly lighter, thinner and smaller, chip manufacturers often embed a device directly in the substrate. However, different manufacturers have been following different standards to develop their own process of embedding the device.

One of the widely used manufacturing methods of a device-embedded substrate is the cavity method, in which a cavity is formed in a CCL (copper clad laminate) before covering a lower surface of the CCL by attaching an adhesive film on the lower surface of the CCL followed by mounting a device in the cavity of the CCL.

Then, an insulator is stacked on an upper surface of the CCL, and after the adhesive film is removed, an insulator is also stacked on the lower surface of the CCL. Thereafter, the device-embedded substrate is fabricated by forming a via and a pattern on each of the insulators.

In this case, since the adhesive film, which is not an actual element of the embedded substrate, is used, unnecessary processes are carried out, and unnecessary materials are used, possibly lowering the productivity. In addition, the tackiness of the adhesive film makes it difficult to remove the adhesive film thoroughly and can cause defect in the production due to the foreign substance of the adhesive film left on the pattern.

### TECHNICAL PROBLEM

The present invention provides a method for manufacturing an embedded substrate that can simplify the manufacturing process and save the materials. The present invention also provides a method for manufacturing an embedded substrate that can prevent any foreign substance left on the pattern from its source.

### TECHNICAL SOLUTION

An aspect of the present invention features a method for manufacturing an embedded substrate. According to an embodiment of the present invention, the method for manufacturing an embedded substrate, which includes a core substrate formed with a pattern on both surfaces thereof and formed with a cavity penetrating from an upper part thereof to a lower part thereof, a chip embedded in the cavity, and a first insulator and a second insulator provided respectively on either surface of the core substrate so as to protect the pattern, can include: preparing the core substrate; laminating the first insulator on a lower surface of the core substrate so as to cover a lower side of the cavity; forming an adhesive layer on the first insulator that is exposed through the cavity; embedding the chip in the cavity by attaching the chip on the adhesive layer; and laminating the second insulator on an upper surface of the core substrate.

The core substrate can be made of a material comprising a metal.

In the laminating of the first insulator and in the laminating of the second insulator, the first insulator and the second insulator can be flowed in the cavity, whereas the first insulator and the second insulator can be in a semi-hardened state.

The adhesive layer can include epoxy resin.

After the embedding of the chip, the epoxy can be cured so as to fix the chip.

### ADVANTAGEOUS EFFECTS

According to an embodiment of the present invention, the productivity of embedded substrate production can be improved because the process can be simplified and the materials can be saved.

Moreover, by preventing any foreign substance of an adhesive film from being left on the pattern from its source, the defective production of the embedded substrate can be decreased.

### DESCRIPTION OF DRAWINGS

FIG. 1 is a flow diagram illustrating a method for manufacturing an embedded substrate in accordance with an embodiment of the present invention.

FIG. 2 to FIG. 6 illustrate manufacturing processes of an embedded substrate in accordance with an embodiment of the present invention.

### MODE FOR INVENTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, an embodiment of a method for manufacturing an embedded substrate according to the present invention will be described in detail with reference to the accompanying drawings. Identical or corresponding elements will be given the same reference numerals, regardless of the figure number, and any redundant description of the identical or corresponding elements will not be repeated.

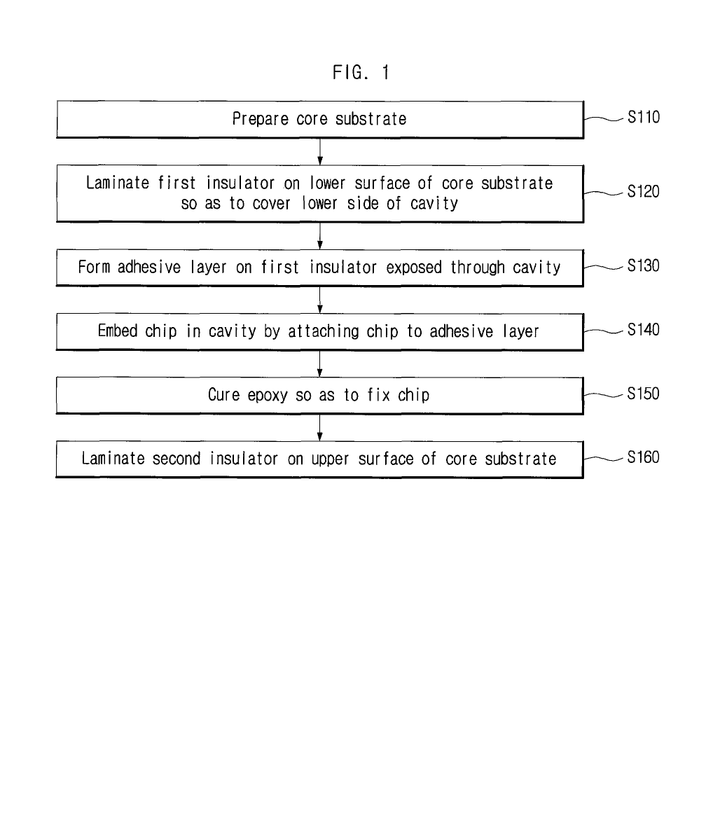

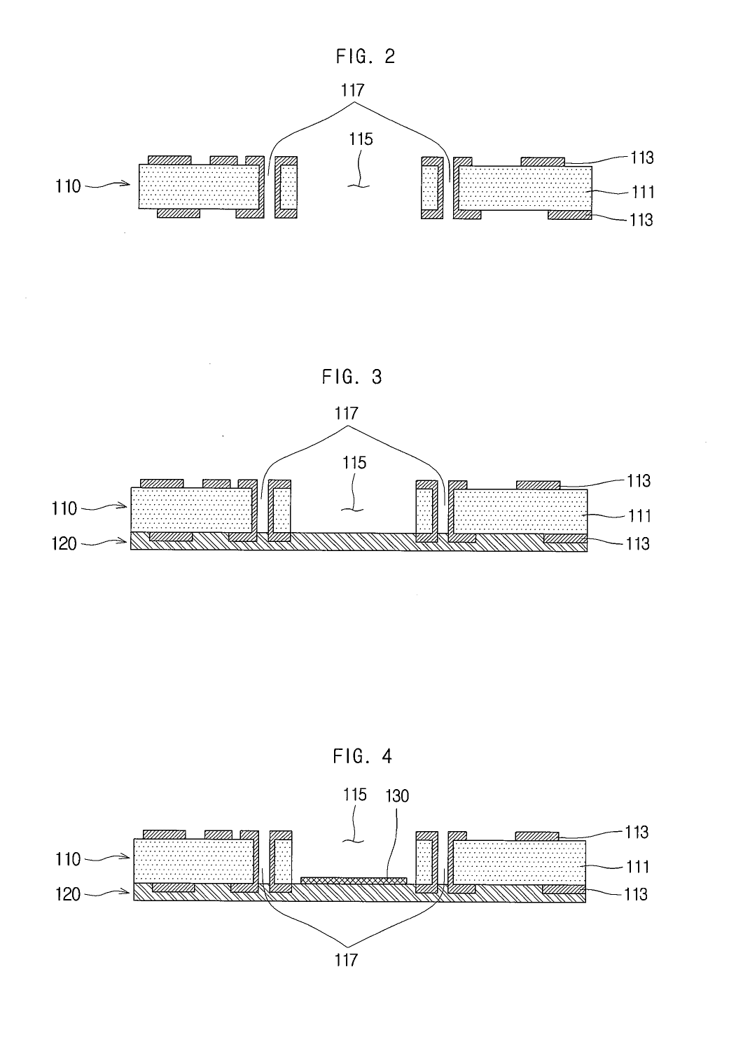

FIG. 1 is a flow diagram illustrating a method for manufacturing an embedded substrate 100 in accordance with an embodiment of the present invention, and FIG. 2 to FIG. 6 illustrate manufacturing processes of the embedded substrate 100 in accordance with an embodiment of the present invention.

The method for manufacturing the embedded substrate 100 will be described with reference to FIG. 1 to FIG. 7.

The embedded substrate 100 includes a core substrate 110, which forms a center layer, a chip 140, which is embedded in the core substrate 110, and a first insulator 120 and a second insulator 150, which cover either surface of the core substrate 110.

To fabricate the embedded substrate 100, the following processes are carried out.

Firstly, as illustrated in FIG. 2, the core substrate 110 is prepared (S110).

The core substrate 110 can include a metal layer 111 that is made of a material that gives rigidity so as to minimize the warpage caused by the thinner embedded substrate 100. The metal layer 111 can be made of copper and the like, and both sides of the metal layer 111 are formed with an insulation layer (not shown), such as an oxide layer, on which a pattern 113 is formed by, for example, exposure. Moreover, the thickness of the metal layer 111 can be made to be the same as that of the chip 140 so as to minimize the thickness of the embedded substrate 100. Here, being the same shall mean being substantially the same with a tolerance in design and production.

Then, a cavity 115 that penetrates the metal layer 111 from an upper part to a lower part is formed. That is, the core substrate 110 is formed with the cavity 115 so that the chip 140 can be embedded. Since the chip 140 is embedded inside the cavity 115 through a later process, the cavity 115 is formed to have a wider transverse area than that of the chip 140 in order to form sufficient space for embedding the chip 140. For example, the cavity 115 can be formed using a drill to penetrate the core substrate 110 from its upper part to its lower part.

After preparing the core substrate 110, the first insulator 120 is laminated on a lower surface of the core substrate 110 to cover a lower side of the cavity 115 (S120), as illustrated in FIG. 3. The first insulator 120 is an element that ultimately remains for interlayer insulation of the embedded substrate 100 manufactured in accordance with the present embodiment, and becomes to cover the pattern 113 formed on the core substrate 110.

As such, since in this embodiment the lower surface of the core substrate 110, in which the cavity 115 is formed, is directly covered by use of the first insulator 120, which remains ultimately, there is no need to incidentally use an adhesive film, like in the prior art. Accordingly, the cost of material can be saved because no such unnecessary material as the adhesive film is used, and the manufacturing process can be simplified because the process of attaching and removing the adhesive film can be omitted.

The first insulator 120 is in a semi-hardened state. Once the semi-hardened state of the first insulator 120 is pressed and hardened through lamination, the first insulator 120 not only is flowed in the cavity 115 and a via hole 117 but also covers the pattern 113 so as to protect the pattern 113. By laminating the semi-hardened state of the first insulator 120, there is no need to carry out a process of filling and hardening the via hole, thereby simplifying the process and improving the productivity.

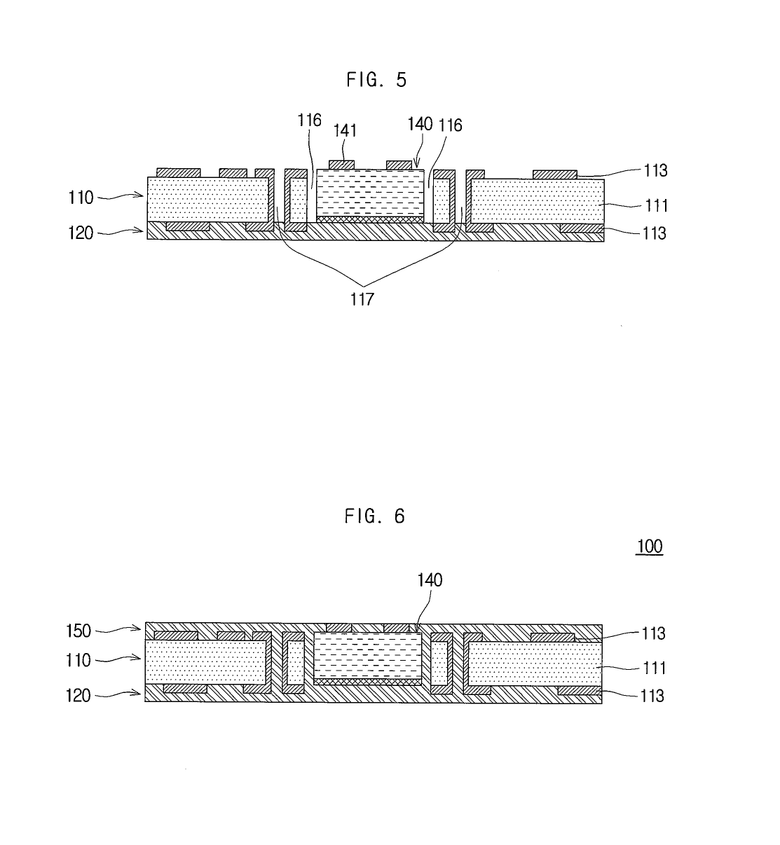

After laminating the first insulator 120, an adhesive layer 130 is formed on the first insulator 120 that is exposed through the cavity 115 (S130), as illustrated in FIG. 4. The adhesive layer 130 is a means for fixing a chip (see reference numeral 140 in FIG. 5) and can be made of, for example, epoxy resin. The adhesive layer 130 fixes the chip 140 to the substrate to prevent the chip 140 from shaking and allows the chip 140 to be structurally integrated in the embedded substrate 100.

Next, as illustrated in FIG. 5, the chip 140 is embedded in the cavity 115 by attaching the chip 140 to the adhesive layer 130 (S140).

The chip 140 is embedded in the cavity 115. The chip 140 is embedded as a device in the cavity 115 so as to minimize the thickness of the embedded substrate 100. Formed on one surface of the chip 140 is a pad 141 for electrical connection with the core substrate 110. When embedding the chip 140 in the core substrate 110, the surface of the chip 140 on which the pad 141 is formed is arranged to face upward so that the pad 141 can be placed on the opposite surface of the chip 140 to which epoxy is attached.

Then, the epoxy is cured so that the chip 140 is completely fixed to the core substrate 110 (S150). That is, by heating the core substrate 110 and curing the epoxy, the first insulator 120 and the chip 140 become physically integrated by the epoxy. Since the thickness of the chip 140 embedded in the cavity 115 and the thickness of the metal layer 111 are made the same, the cavity 115 becomes raised by as much as the thickness of the formed epoxy, and thus the pad 141 can be exposed to the outside of the second insulator 150 through a later process of laminating the second insulator 150.

Then, as illustrated in FIG. 6, the second insulator 150 is laminated on an upper surface of the core substrate 110 (S160). Like the first insulator 120, the second insulator 150 can be in a semi-hardened state. By laminating the semi-hardened state of the second insulator 150, the second insulator 150 is flowed in the cavity 115 and the via hole 117.

As such, since a gap 116 and the via hole 117 are filled up between the chip 140 and the cavity 115 when the first insulator 120 and the second 150 are laminated, a separate process for securely fixing the chip 140, for example, a process of filling and curing a liquid material in the gap 116, is not carried out, thereby simplifying the process.

Although not illustrated in the drawings, it is possible to carry out an additional build-up process on the first and second insulators 120, 150, after laminating the second insulator 150, in order to manufacture the embedded substrate 100 having 4 or more layers of circuit. According to the present embodiment, multi-layer patterns 113 can be formed symmetrically on either surface of the core substrate 110, and thus the embedded substrate 100 can have a stable structure. That is, in case warpage occurs in the substrate due to external force exerted on the substrate, the symmetric structure allows the external force to diverge to both surfaces without converging in one surface, keeping the substrate in a stable structure.

Since the method for manufacturing the embedded substrate in accordance with this embodiment does not include a process of attaching and removing an adhesive film, the manufacturing process can be simplified, and the material can be saved, thereby improving the productivity of embedded substrate production.

Furthermore, by preventing any foreign substance of an adhesive film from being left on the pattern from its source, the defective production of the embedded substrate can be decreased.

Although a certain embodiment of the present invention has been described, it shall be appreciated by anyone ordinarily skilled in the art to which the present invention pertains that there can be a variety of permutations and modifications of the present invention without departing from the technical ideas and scopes of the present invention that are disclosed in the claims appended below.

A large number of embodiments in addition to the above-described embodiment are present within the claims of the present invention.

What is claimed is:

1. A method for manufacturing an embedded substrate, the embedded substrate comprising a core substrate formed with a pattern on both surfaces thereof and formed with a cavity penetrating from an upper part thereof to a lower part thereof, a chip embedded in the cavity, and a first insulator and a second insulator provided respectively on either surface of the core substrate so as to protect the pattern, the method comprising:
preparing the core substrate;
laminating the first insulator on a lower surface of the core substrate so as to cover a lower side of the cavity;
forming an adhesive layer on the first insulator that is exposed through the cavity;
embedding the chip in the cavity by attaching the chip on the adhesive layer; and
laminating the second insulator on an upper surface of the core substrate.

2. The method of claim 1, wherein the core substrate is made of a material comprising a metal.

3. The method of claim 1, wherein, in the laminating of the first insulator and in the laminating of the second insulator, the first insulator and the second insulator are flowed in the cavity, whereas the first insulator and the second insulator are in a semi-hardened state.

4. The method of claim 1, wherein the adhesive layer comprises epoxy resin.

5. The method of claim 4, further comprising, after the embedding of the chip, the epoxy is cured so as to fix the chip.
